(19) United States
(12) Patent Application Publication
(10) Pub. No.: US 2013/0161734 A1
(43) Pub. Date: Jun. 27, 2013

(54) TRANSISTOR STRUCTURE AND METHOD FOR PREPARING THE SAME

(71) Applicant: Tieh Chiang WU, Taoyuan County (TW)

(72) Inventor: Tieh Chiang WU, Taoyuan County (TW)

(73) Assignee: Nan Ya Technology Corporation, Kueishan (TW)

(21) Appl. No.: 13/335,318

(22) Filed: Dec. 22, 2011

(51) Int. Cl. H01L 29/78

(52) U.S. Cl. 257/330; 257/E29.262

(57) ABSTRACT

A buried channel transistor has a semiconductor substrate, a trench and a doped region. The semiconductor substrate has a first surface and a well under the first surface. The trench is disposed in the semiconductor substrate and extends from the first surface into the well. The trench includes a buried gate structure inside the trench. The buried gate structure has a first workfunction layer, a second workfunction layer with a dopant type opposite to that of the first workfunction layer. The second workfunction layer is disposed adjacent to the first workfunction layer. The buried gate structure further includes a dielectric layer adjacent to the trench inner sidewall. The dielectric layer separates the workfunction layers from the semiconductor substrate. The doped region is disposed in the semiconductor substrate and located above the well. The dopant type of the doped region is opposite to that of the first workfunction layer.

### DESCRIPTION

1. Technical Field

The present invention relates to a transistor structure and method for preparing the same, and more particularly, to a buried channel transistor structure and a method for preparing the same.

2. Background

As semiconductor fabrication technology continues to improve, sizes of electronic devices are reduced, and the size and the channel length of the conventional planar channel transistor also decrease correspondingly. The conventional planar channel transistor has been widely used in integrated circuit design; however, the continuous reduction of the size and the channel length of the planar channel transistor results in a serious interaction between the source/drain and the carrier channel under the control gate. The capability to control the transistor's switching operation effectively is challenged by numerous phenomena such as short channel effect, which impedes the functioning of the planar channel transistor. To address this problem, researchers developed the so-called buried channel transistor with a buried gate sandwiched between the two doped regions and an increased channel length. Although the short channel effect is improved, the high electric field at the boundary between the source/drain region and the buried poly gate layer is reported as the key factor in GIDL (Gate Induced Drain Leakage) failures.

### SUMMARY

One aspect of the present invention provides several embodiments to reduce the occurrence of the GIDL failure in the buried channel transistor.

In one embodiment of the present invention, a buried channel transistor has a semiconductor substrate, a trench and a doped region. The semiconductor substrate has a first surface and a well disposed under the first surface. The trench is disposed in the semiconductor substrate and extends from the first surface into the well. Furthermore, the trench includes a buried gate structure inside the trench. The buried gate structure has a first workfunction layer, a second workfunction layer with a dopant type opposite to the dopant type of the first workfunction layer, and the second workfunction layer is disposed adjacent to the first workfunction layer. The buried gate structure further includes a dielectric layer wherein the dielectric layer is adjacent to the trench inner sidewall. The dielectric layer is configured to separate said workfunction layers from the semiconductor substrate. The doped region is disposed in the semiconductor substrate and located above the well wherein the dopant type of the doped region is opposite to the dopant type of the first workfunction layer.

According to an embodiment of the present invention, the doped region is separated from the workfunction layers by the dielectric layer.

According to an embodiment of the present invention, the buried gate structure's second workfunction layer is disposed on the first workfunction layer, wherein the second workfunction layer is configured to separate the first workfunction layer from the doped region.

According to an embodiment of the present invention, the second workfunction layer is disposed on the first workfunction layer. The dopant concentration in the second workfunction layer is distributed in a gradient and the dopant concentration in the first workfunction layer is distributed in a gradient.

According to an embodiment of the present invention, the transistor's second workfunction layer is disposed along a part of the trench inner sidewall and the first workfunction layer is sandwiched between the second workfunction layers.

According an embodiment of the present invention, the first workfunction layer is formed on the trench bottom and a part of the inner sidewall of the trench.

In order to make the aforementioned and other features and advantages of the present invention more comprehensible, preferred embodiments accompanied with figures are described in detail below.

### BRIEF DESCRIPTION OF THE DRAWINGS

The objectives of the present invention will become apparent upon reading the following description and upon reference to the accompanying drawings in which:

FIG. 1 is a cross-sectional view showing a part of a preferred embodiment of the present invention.

FIG. 2 is a cross-sectional view showing a preferred embodiment of the present invention.

FIG. 3 is a cross-sectional view showing a preferred embodiment of the present invention.

FIG. 4 is a cross-sectional view showing a preferred embodiment of the present invention.

FIG. 5A is a cross-sectional view showing a preferred embodiment of the present invention.

FIG. 5B is a top view showing a preferred embodiment of the present invention.

FIG. 6 is a cross-sectional view showing a preferred embodiment of the present invention.

FIG. 7 is a cross-sectional view showing a preferred embodiment of the present invention.

### DETAILED DESCRIPTION

Reference will now be made in detail to the present embodiments of the invention, examples of which are illustrated in the accompanying drawings.

The term “semiconductor substrate” used in the present preferred embodiments may refer to a p-type or n-type wafer substrate made with semiconductor material, and the wafer may be but is not limited to a slice cut from a crystal ingot or a grown epitaxial layer. The term “n-type doping/doped” used in the description hereinafter is to represent adding electron increasing dopants/impurities including but not limited to V, VI group atoms into a material matrix in order to manipulate the carrier numbers. Similarly, the term “p-type doping/doped” used in the description hereinafter is to represent adding hole increasing dopants/impurities including but not limited to II, III group atoms into a material matrix in order to manipulate the carrier numbers.

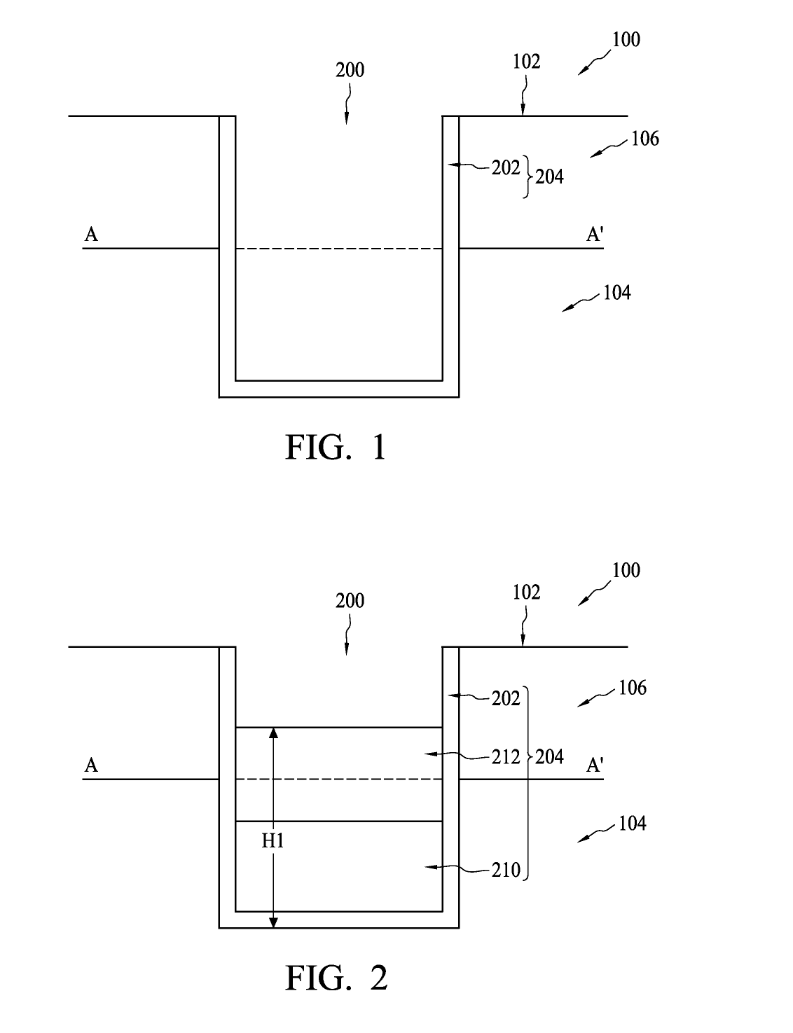

A detailed description of buried gate transistors, and methods for manufacturing such transistors, is provided with reference to FIGS. 1-7.

Referring to FIG. 1, a semiconductor substrate 100 is provided. The semiconductor substrate 100 has a zone underneath its first surface 102 which is called well 104. The well 104 may be neutral, n-type or p-type doped. The semiconductor substrate 100 may further include a doped region 106 which can be formed by implanting, diffusing, in-situ doped or epi-growth dopant/impurities such as P, As, B, In, Sb etc. into the substrate. The doped region 106 is disposed above the well 104. In one embodiment according to the present invention, the doped region 106 is an n-type region. In another embodiment according to present invention, the doped region can be p-type. The depth of the doped region 106 underneath the first surface 102 is about 0.1 um, and preferably between 0.05 um and 0.2 um. A line AA′ is drawn to depict the boundary between the well 104 and the doped region 106. Furthermore, a part of the semiconductor substrate 100 is excavated to form a trench 200 under the first surface 102. The trench 200 extends from the first surface 102 into the well 104. The excavation process to form the trench 200 can be selected from various semiconductor etch processes including but not limited to RIE (reactive ion etch), wet etch, etc. The process to be selected is dependent on the dimension or the aspect ratio of the trench. In an embodiment according to the present invention, the aspect ratio is between 1 and 20, and preferably between 4 and 8. The aspect ratio of the trench described herein is defined as the ratio of the longer dimension, such as the depth of the trench, to the shorter dimension, such as the diameter of the trench.

A buried gate structure 204 is formed in the trench 200 to provide a voltage controllable device under the semiconductor substrate 100 first surface 102, as partially illustrated in FIG. 1. The dielectric layer 202 is formed in the trench 200 along the trench's bottom and sidewall. The process used to grow the dielectric layer 202 includes but is not limited to CVD (Chemical Vapor Deposition) or thermal oxidation. The material used for forming the dielectric layer 202 may be selected from films with high dielectric constant, also called k value, such as silicon oxide, silicon nitride, silicon oxinitride, metal oxides such as the oxide compound of Hf, Zr, Ru, Al, Ti etc., or other suitable material chosen for compatibility. The thickness of the dielectric layer 202 is preferably between 1 and 10 nm.

FIG. 2 further illustrates a part of the buried gate structure 204. The gate structure 204 includes two conductive layers which fill a part of the trench 200 and are isolated from the doped region 106 by the dielectric layer 202. One of the two conductive layer is called the first workfunction layer 210 and the other one is called the second workfunction layer 212, wherein the second workfunction layer 212 is stacked on the first workfunction layer 210. The dopant type of the first workfunction layer 210 is opposite to the dopant type of the second workfunction layer 212 and the doped region 106. In one embodiment according to the present invention, the first workfunction layer 210 is preferably made with p-type conductive material and the second workfunction layer 212 is made with n-type conductive material. For another embodiment according to the present invention, the first workfunction layer 210 is preferably made with n-type conductive material and the second workfunction layer 212 is made with p-type conductive material. The material of the matrix for the conductive layer 210 or 212 is semi-conductive or conductive material such as polysilicon, amorphous silicon, metal or other suitable material chosen for compatibility.

The first and second workfunction layers fill a part of the trench 200, preferably to fill up to a level with height H1 (measured from the trench bottom) such that the top of the second workfunction layer 212 is higher than the boundary line AA′. The process to grow the workfunction layers in the trench can be firstly conducted by a CVD or PVD process for the first layer growth, then etching back by a dry or wet etch process followed by a CVD or PVD process for the second layer growth.

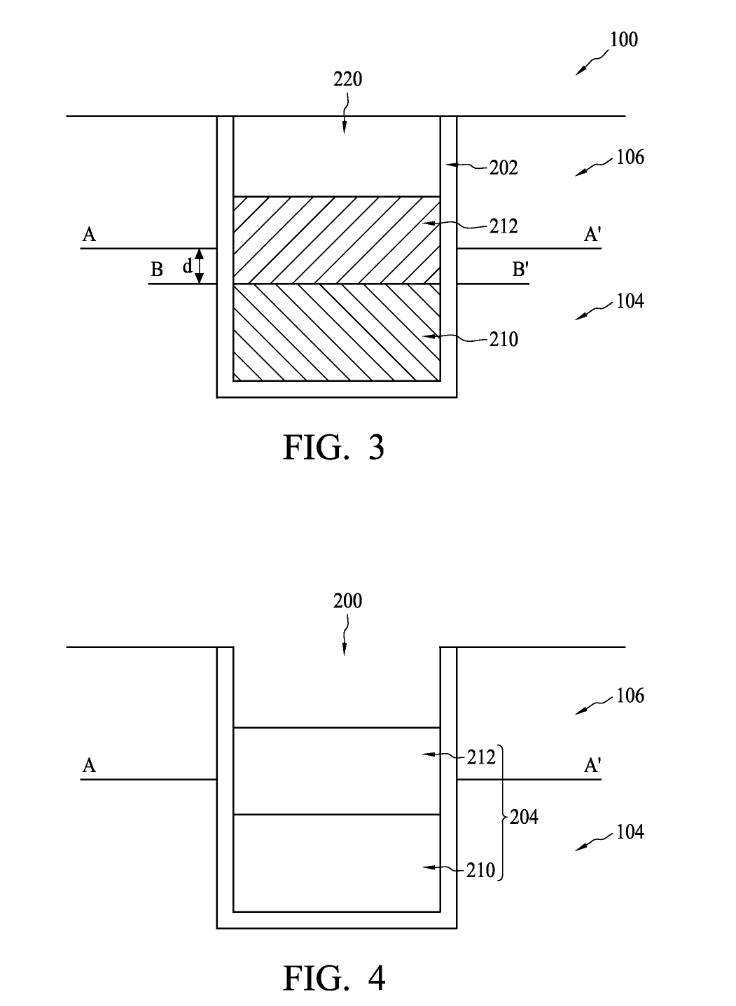

As illustrated by FIG. 3, a line BB′ is drawn to depict the boundary between the first workfunction layer 210 and the second workfunction layer 212. According to a preferred embodiment of the present invention, line BB′ is closer to the trench bottom than line AA′. The distance d between line AA′ and line BB′ is preferably between 0 um and 0.1 um. Therefore, the first workfunction layer 210 is separated from the doped region 106 by the second workfunction layer 212 and the dielectric layer 202. In another embodiment, a fill-dielectric 220 stacked on the second workfunction layer 212 can be introduced into the trench 200 in order to create a planar substrate surface.

As illustrated by FIG. 4, another embodiment of the present invention has a p-type doped region 106 in the substrate 100, and the buried gate structure 204 has an n-type second workfunction layer 212 stacked on a p-type first workfunction layer 210.

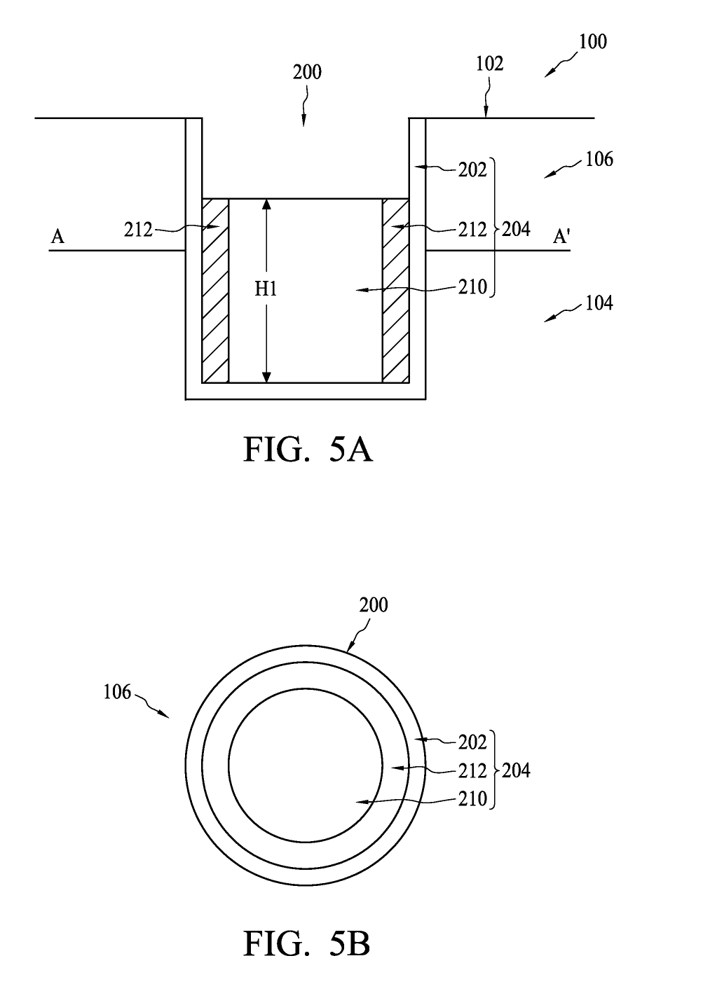

FIG. 5A illustrates another embodiment according to the present invention. This embodiment has a trench 200 with structure similar to the above-described embodiments. Instead of having stacked workfunction layers inside the buried gate structure 204, the second workfunction layer 212 grows adjacent to the dielectric layer 202 with a thickness of between 1 nm to 100 nm. The first workfunction layer 210 is formed thereafter in the trench 200 and is sandwiched between the second workfunction layers 212. FIG. 5B is a top view of the buried gate structure 204. The first workfunction layer 210, the second workfunction layer 212, and the dielectric layer 202 together form a ring pattern inside the trench 200. With such arrangement, the first workfunction layer 210 is separated from the substrate's doped region 106 by the dielectric layer 202 and the second workfunction layers 212. Moreover, the dopant type of the first workfunction layer 210 is preferably opposite to the dopant type of the second workfunction layer 212 and the doped region 106. The first and second workfunction layers together fill a part of the trench 200, preferably to fill up to a level with height H1 (measured from the trench bottom) such that the top of the second workfunction layer 212 is higher than the boundary line AA′ between the well 104 and the doped region 106. H1 is preferably between 10 nm and 500 nm.

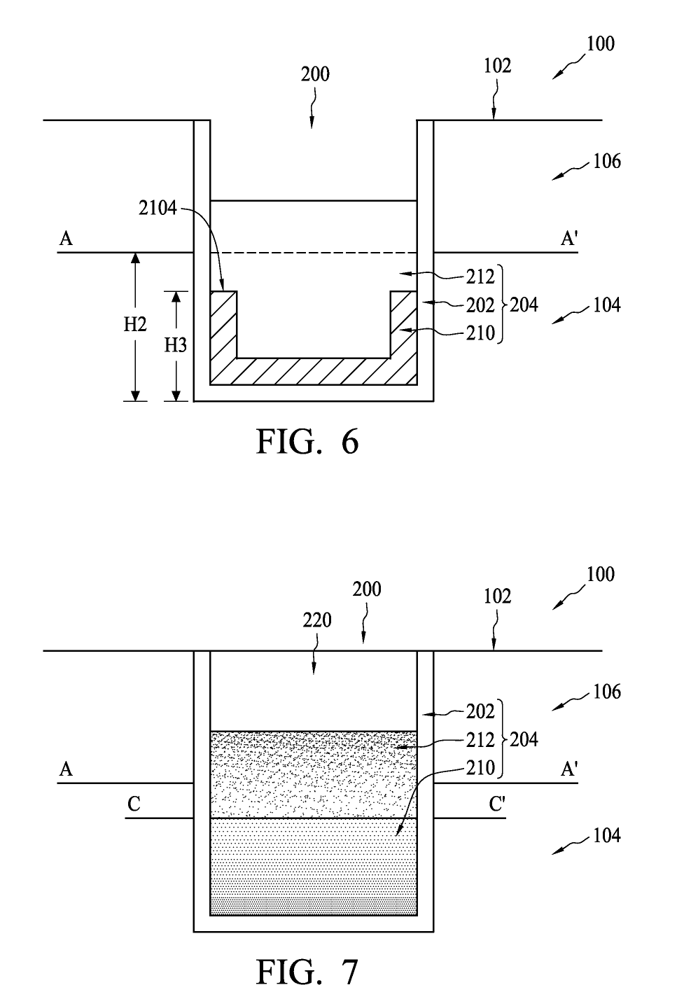

FIG. 6 depicts another embodiment according to the present invention. A trench 200 is formed in a semiconductor substrate 100 after a doped region 106 is formed under the first surface 102. A dielectric layer 202 sequentially grows along the bottom and inner sidewall of the trench 200. A first workfunction layer 210 possesses a dopant type which is opposite to the dopant type of the second workfunction layer 212 and the doped region 106.

The first workfunction layer 210 is formed along the bottom and a part of the inner sidewall of the trench 200. The thickness of the first workfunction layer 210 is preferably between 1 nm and 100 nm. Height H3, measured from the trench bottom to the top of the first workfunction layer 210, is less than height H2, which is measured from the trench bottom to the boundary line AA′. Therefore, the boundary between the well 104 and the doped region 106 is higher than the top of the sidewall section 2104 of the first workfunction layer 210. A second workfunction layer 212 is filled later into the trench 200 and partially surrounded by the first workfunction layer 210. The purpose of having height H3 less than height H2 is to ensure that the first workfunction layer 210 is separated from the doped region 106 by the dielectric layer 202 and the second workfunction layer 212.

The present invention further discloses an embodiment as illustrated in FIG. 7. A trench 200 is formed in a semiconductor substrate 100. The semiconductor substrate 100 has a well 104, which is underneath a first surface 102. A doped region 106 is located between the first surface 102 and the well 104. A line AN is drawn to depict the boundary between the well 104 and the doped region 106. Line AA′ can be a straight line or can be a connection of multiple small line segments separating the well 104 and the doped region 106. The doped region 106 can be an n-type or a p-type region, and the n-type is selected in this embodiment. A dielectric layer 202 is formed along the bottom and inner sidewall of the trench 200 with a thickness ranging from 1 nm to 20 nm. Thereafter, a p-type first workfunction layer 210 starts forming from the bottom of the trench 200 to line CC′, which is under line AA′. The dopant concentration in the first workfunction layer 210 is distributed in a gradient. The p-type dopant concentration is preferably greatest at the trench bottom and decreases gradually from bottom up. An n-type second workfunction layer 212 is subsequently formed on the p-type first workfunction layer 210. The dopant concentration in the second workfunction layer 212 is distributed in a gradient which has lowest n-type dopant concentration at the bottom and increases gradually from bottom up. The p-type first workfunction layer 210 is separated from the doped region 106 by the n-type second workfunction layer 212 and the dielectric layer 202. Subsequently, a dopant gradient buried structure 204 is formed within the trench 200. In another embodiment, a fill-dielectric 220 stacked on the second workfunction layer 212 can be introduced into the trench 200 in order to create a planar substrate surface.

Although the preferred embodiments of the present invention have been disclosed for illustrative purposes, those skilled in the art will appreciate that various modifications, additions and substitutions are possible, without departing from the scope and spirit of the invention as described in the accompanying claims

What is claimed is:

1. A buried channel transistor, the transistor comprising:
a semiconductor substrate comprising a first surface and a well, wherein the well is under the first surface;
a trench disposed in the semiconductor substrate and extending from the first surface into the well wherein the trench comprises a buried gate structure, the buried gate structure comprises a first workfunction layer, a second workfunction layer with a dopant type opposite to the dopant type of the first workfunction layer and disposed adjacent to the first workfunction layer, and a dielectric layer, wherein the dielectric layer is adjacent to the trench inner sidewall and configured to separate said workfunction layers from the semiconductor substrate; and
a doped region disposed in the semiconductor substrate and above the well, wherein the dopant type of the doped region is opposite to the dopant type of the first workfunction layer.

2. The transistor of claim 1, wherein the second workfunction layer is configured to separate the first workfunction layer from the doped region.

3. The transistor of claim 2, wherein the second workfunction layer is disposed on the first workfunction layer.

4. The transistor of claim 3, wherein the boundary between the well and the doped region is higher than the boundary between the first workfunction layer and the second workfunction layer, and the first workfunction layer is p-type.

5. The transistor of claim 3, wherein the boundary between the well and the doped region is higher than the boundary between the first workfunction layer and the second workfunction layer, and the first workfunction layer is n-type.

6. The transistor of claim 2, wherein the second workfunction layer is disposed along a part of the trench inner sidewall and the first workfunction layer is sandwiched between the second workfunction layers.

7. The transistor of claim 6, wherein the top of the second workfunction layers is higher than the boundary between the well and the doped region.

8. The transistor of claim 7, wherein the first workfunction layer is p-type.

9. The transistor of claim 7, wherein the first workfunction layer is n-type.

10. The transistor of claim 1, wherein the first workfunction layer is formed on the trench bottom and a part of the inner sidewall of the trench.

11. The transistor of claim 10, wherein the boundary between the well and the doped region is higher than the top of the sidewall section of the first workfunction layer.

12. The transistor of claim 11, wherein the second workfunction layer is filled in the trench and the top of the second workfunction layer is higher than the boundary between the well and the doped region, and the second workfunction layer is configured to separate the first workfunction layer from the doped region.

13. The transistor of claim 12, wherein the first workfunction layer is p-type.

14. The transistor of claim 12, wherein the first workfunction layer is n-type.

15. The transistor of claim 2, wherein the dopant concentration in the first workfunction layer is distributed in a gradient.

16. The transistor of claim 15, wherein the dopant concentration in the first workfunction layer is highest at the trench bottom and decreases gradually from bottom up.

17. The transistor of claim 2, wherein the dopant concentration in the second workfunction layer is distributed in a gradient.

18. The transistor of claim 17, wherein the dopant concentration in the second workfunction layer is lowest at the boundary between the first workfunction layer and the second workfunction layer.

19. The transistor of claim 2, wherein the second workfunction layer is disposed on the first workfunction layer, and the dopant concentrations in the first and second workfunction layers are distributed in a gradient.

20. The transistor of claim 19, wherein the boundary between the well and the doped region is higher than the boundary between the first workfunction layer and the second workfunction layer.

21. The transistor of claim 19, wherein the first workfunction layer is p-type.

22. The transistor of claim 19, wherein the first workfunction layer is n-type.
